(19) United States
(12) Patent Application Publication
(10) Pub. No.: US 2007/0047637 A1
(43) Pub. Date: Mar. 1, 2007

(54) Channel equalizer, channel equalization method, and tap coefficient updating method

(76) Inventor: Dong-hoon Lee, Suwon-si (KR)

Correspondence Address: STANZIONE & KIM, LLP, 919 18TH STREET, N.W., SUITE 440, WASHINGTON, DC, 20006, US

(21) Appl. No.: 11/431,712

(22) Filed: May 11, 2006

(30) Foreign Application Priority Data
Aug. 29, 2005 (KR) 2005-79700

(51) Int. Cl. H03H 7/30; H04B 1/10

(52) U.S. Cl. 375/233; 375/350

(57) ABSTRACT

A channel equalizer to equalize a signal received over a transmission channel, includes a feedforward filter to filter the received signal, a level determination unit to determine a first level value among a plurality of predetermined amplitude levels based on an amplitude of an output signal of the feedforward filter, and an error calculation unit to calculate a first error value based on the amplitude of the output signal of the feedforward filter and the first level value and to output the first error value to the feedforward filter so that the feedforward filter updates a tap coefficient thereof using the first error value. As such, the channel equalizer is capable of operating independently of a phase error by using the amplitude of the received signal in channel equalization, whereby a variety of designs can be available for the channel equalizer regardless of a sequence of a carrier recovery operation and a channel equalization operation.

### CROSS-REFERENCE TO RELATED APPLICATIONS

This application claims the benefit under 35 U.S.C. § 119 from Korean Patent Application No. 2005-79700, filed on Aug. 29, 2005, the entire content of which is incorporated herein by reference.

### BACKGROUND OF THE INVENTION

1. Field of the Invention

The present general inventive concept relates in general to a channel equalizer, a channel equalization method, and a tap coefficient updating method. More specifically, the present general inventive concept relates to a channel equalizer and a channel equalization method, in which the channel equalizer operates independently of a phase error by using an amplitude of a received signal in a channel equalization operation, whereby a variety of designs can be available for the channel equalizer regardless of a sequence of a carrier recovery operation and the channel equalization operation, and a tap coefficient updating method usable therein.

2. Description of the Related Art

FIG. 1 is a functional block diagram illustrating a conventional decision feedback equalizer (DFE), which updates a tap coefficient by using a Stop-and-Go (SAG) algorithm.

The DEF includes a feedforward filter 10, a first subtracter 20, a slicer 30, a second subtracter 40, and a feedback filter 50. As illustrated in FIG. 1, a span range of the feedforward filter 10 and a span range of the feedback filter 50 are overlapped with each other.

The feedforward filter 10 filters a signal received over a transmission channel. The filtering performed by the feedforward filter cancels a pre-ghost.

The feedback filter 50 filters a signal which has been previously equalized by the channel equalizer (i.e., the DFE). This signal may be an output signal z(n) from the first subtracter 20, or a slicer output signal z(n) (if there is a slicer 30) which has undergone a decision-directed operation. The feedback filter 50 may remove a post-ghost.

The first subtracter 20 subtracts a first signal, which has been filtered by the feedback filter 50, from a second signal, which has been filtered by the feedforward filter 10, and outputs a resulting signal z(n). This output signal z(n) corresponds to a signal from a receiver, from which the pre-ghost and the post-ghost components are removed. The slicer 30 computes a decision based on the output signal z(n) from the first subtracter 20 and outputs a decision value.

The second subtracter 40 subtracts the slicer output signal (i.e., the decision value) from the signal z(n) to obtain an error signal, and outputs the resulting error signal to the feedforward filter 10 and feedback filter 50.

The feedforward filter 10 and the feedback filter 50 update the respective tap coefficients using the error signal provided by the second subtracter 40.

A typical example of a method for updating coefficients of each filter in a channel equalizer is the least mean square (LMS) algorithm. A filter coefficient updating equation based on the LMS algorithm can be expressed as follows:
w(n+1)=w(n)−μr(n)e(n) [Equation 1]
where w(n) represents a tap coefficient vector of a filter, r(n) represents a received signal vector, μ represents a step size, and e(n) represents an error signal.

When a decision-directed (DD) algorithm is used, the error signal e(n) can be expressed as follows:
e^{DD}(n)=z(n)−_{\hat{α}}(n) [Equation 2]
where z(n) is the output signal of the channel equalizer (i.e., the DFE), and \hat{α}(n) is a closest constellation value to the signal z(n). FIG. 2A illustrates constellation values (marked as ‘x’s) of a signal transmitted over a transmission channel using 16-QAM modulation mode. When the first subtracter 20 outputs the signal z(n), the slicer 30 decides the closest constellation value as \hat{α}(n). Thus, the difference between the output signal z(n) and the closest constellation value \hat{α}(n) becomes the error signal e^{DD}(n).

On the other hand, when the reduced constellation algorithm (RCA) is used, the error signal e(n) can be expressed as follows:
e^{RCA}(n)=z(n)−_{\hat{b}}(n) [Equation 3]
where z(n) is the output signal of the channel equalizer (i.e., the DFE), and \hat{b}(n) is a reduced constellation value, which is obtained by the following equation.

$${b}_{l} = \frac{{Q}_{{a}_{k} {HS}_{l}} {\vert {a}_{k} \vert}^{2}}{{( {Q}_{{a}_{k} {HS}_{l}} {a}_{k} )}^{*}}$$

where Sₗ(l=1, 2, 3, 4) is a set of constellation values that belong to quadrants 1, 2, 3 and 4, respectively. FIG. 2B illustrates the reduced constellation values (marked as ‘Δ’s) in the 16-QAM modulation mode.

Based on the description provided above, a filter tap coefficient updating method based on the SAG algorithm proposed by Picchi will be explained. Here, an error signal is derived by the DD algorithm. However, tap coefficients of a filter are updated if and only if the sign of the error signal derived using the DD algorithm coincides with the sign of the error signal derived using the RCA. Otherwise, the tap coefficients of the filter are not updated. The tap coefficient calculation based on the SAG algorithm can be achieved by the following equations.
W_{R}(n+1)=W_{R}(n)−μ(f_{n,R}e_{R}^{DD}(n)r_{R}(n)+f_{n,l}e_{I}^{DD}(n)r_{I}(n))
W_{I}(n+1)=W_{I}(n)+μ(f_{n,R}e_{R}^{DD}(n)r_{I}(n)−f_{n,I}e_{I}^{DD}(n)r_{R}(n))
wherein w_{R}(n) represents a real number part of the tap coefficient vector w(n), and wₗ(n) represents an imaginary number part of the tap coefficient vector w(n). Also, f_{n,R} and f_{n,l} have values as follows:

$${f}_{n , R} = \{ \begin{matrix}1 , & if sgn ( {e}_{R}^{DD} ( n ) ) = sgn ( {e}_{R}^{RCA} ( n ) ) \\ 0 , & otherwise\end{matrix} \\ {f}_{n , I} = \{ \begin{matrix}1 , & if sgn ( {e}_{I}^{DD} ( n ) ) = sgn ( {e}_{I}^{RCA} ( n ) ) \\ 0 , & otherwise\end{matrix}$$

The SAG algorithm proposed by Picchi is a combination of the RCA and the DD algorithm. The SAG algorithm is useful in that it does not require a training sequence and has a small steady-state mean square error (MSE). However, the SAG algorithm still uses the output signal z(n) of the channel equalizer for generating the error signal. Since the output signal z(n) has both amplitude and phase information, in order to generate a correct error signal, a carrier recovery operation should precede or be performed simultaneously with a channel equalization operation. Nevertheless, when using a 64-QAM modulation mode or 256-QAM modulation mode as in a cable TV standard, the carrier recovery operation needs to be performed after the channel equalization operation, which consequently makes it difficult to apply the SAG algorithm of Picchi.

### SUMMARY OF THE INVENTION

The present general inventive concept provides a channel equalizer and a channel equalization method, in which the channel equalizer operates independently of a phase error by using an amplitude level of a received signal in a channel equalization operation, whereby a variety of designs can be available for the channel equalizer regardless of a sequence of a carrier recovery operation and the channel equalization operation, and a tap coefficient updating method used therein.

Additional aspects of the present general inventive concept will be set forth in part in the description which follows and, in part, will be obvious from the description, or may be learned by practice of the general inventive concept.

The foregoing and/or other aspects of the present general inventive concept are achieved by providing a channel equalizer to equalize a signal received over a transmission channel, including a feedforward filter to filter the received signal, a level determination unit to determine a first level value among a plurality of predetermined amplitude levels based on an amplitude of an output signal of the feedforward filter, and an error calculation unit to calculate a first error value based on the amplitude of the output signal of the feedforward filter and the first level value and to output the first error value to the feedforward filter so that the feedforward filter updates a tap coefficient thereof using the first error value.

The plurality of predetermined amplitude levels may be set based on amplitudes of constellations of the signal transmitted and received over the transmission channel.

The level determination unit may determine the first level value using a threshold defined by the maximum a posteriori (MAP) rule.

Also, the error calculation unit may further calculate a second error value by applying the constant modulus algorithm (CMA) algorithm to the amplitude of the output signal of the subtracter and may output the second error value to the feedforward filter such that the feedforward filter updates the tap coefficient thereof based on the first error value and the second error value.

If a sign of the first error value and a sign of the second error value are the same, the feedforward filter may update the tap coefficient thereof using the first error value.

If a sign of the first error value and a sign of the second error value are not the same, the feedforward filter may not update the tap coefficient thereof.

Alternatively, the feedforward filter may update the tap coefficient thereof using a weighted sum of the first error value and the second error value.

The foregoing and/or other aspects of the present general inventive concept are achieved by providing a channel equalizer to equalize a signal received over a transmission channel, including a feedforward filter to filter the received signal, a feedback filter to filter a signal previously filtered by the channel equalizer, a subtracter to subtract a first filter signal filtered by the feedback filter from a second filter signal filtered by the feedforward filter and to output a resulting signal, a level determination unit to determine a first level value among a plurality of predetermined amplitude levels based on an amplitude of the output signal of the subtracter, and an error calculation unit calculate a first error value based on the amplitude of the output signal of the subtracter and the first level value and to output the first error value to the feedforward filter and the feedback filter so that the feedforward filter and the feedback filter update respective tap coefficients thereof using the first error value.

The channel equalizer may further include a slicer to output a decision value to decide the output signal of the subtracter as the previously equalized signal.

Also, the plurality of predetermined amplitude levels may be set based on an amplitude of constellations of the signal transmitted and received over the transmission channel.

The level determination unit may compare the amplitude of the output signal of the subtracter with the plurality of predetermined amplitude levels to determine a most approximate level value as the first level value.

The level determination unit may determine the first level value using a threshold defined by the MAP (Maximum a posteriori) rule.

The threshold may be determined according to a signal-to-noise (SNR) ratio.

The error calculation unit may calculate a second error value by applying the CMA algorithm to the amplitude of the output signal of the feedforward filter and may output the second error value to the feedforward filter and the feedback filter such that the feedforward filter and the feedback filter update the respective tap coefficients thereof based on the first error value and the second error value.

If a sign of the first error value and a sign of the second error value are the same, the feedforward filter and the feedback filter may update the respective tap coefficients thereof using the first error value.

If a sign of the first error value and a sign of the second error value are not the same, the feedforward filter and the feedback filter may not update the respective tap coefficients thereof.

Alternatively, the feedforward filter and the feedback filter may update the respective tap coefficients thereof using a weighted sum of the first error value and the second error value.

The foregoing and/or other aspects of the present general inventive concept are also achieved by providing a channel equalizer, including at least one filter having a plurality of taps and corresponding tap coefficients, and an error unit to determine an error based on amplitude information of an output of the at least one filter and to feedback the error to the at least one filter such that the at least one filter controls the tap coefficients accordingly.

The foregoing and/or other aspects of the present general inventive concept are also achieved by providing a receiver, including a channel equalizer having at least one filter having a plurality of taps and corresponding tap coefficients, and an error unit to determine an error based on amplitude information of an output of the at least one filter and to feedback the error to the at least one filter such that the at least one filter controls the tap coefficients accordingly.

The foregoing and/or other aspects of the present general inventive concept are also achieved by providing an equalization method, the method including determining an error based on amplitude information of an output of at least one filter, and feeding the determined error back to the at least one filter such that the at least one filter controls tap coefficients thereof accordingly.

The foregoing and/or other aspects of the present general inventive concept are achieved by providing a method of updating a tap coefficient of a filter in a channel equalizer which equalizes a signal received over a transmission channel, the method including determining a first level value among a plurality of predetermined amplitude levels based on an amplitude of an output signal of the filter, calculating a first error value based on the amplitude of the output signal of the filter and the first level value, and updating the tap coefficient using the first error value.

The plurality of predetermined amplitude levels may be set based on an amplitude of constellations of the signal received over the transmission channel.

The determining of the first level value may include determining the first level value using a threshold defined by the maximum a posteriori (MAP) rule.

The method further including: generating a second error value by applying the CMA to the amplitude of the output signal of the filter, updating of the tap coefficient comprises updating the tap coefficient based on the first error value and the second error value.

The updating of the tap coefficient may include updating the tap coefficient using the first error value if a sign of the first error value and a sign of the second error value are the same.

The updating of the tap coefficient may include not updating the tap coefficient if a sign of the first error value and a sign of the second error value are not the same.

The updating of the tap coefficient comprises updating the tap coefficient using a weighted sum of the first error value and the second error value.

The foregoing and/or other aspects of the present general inventive concept are achieved by providing a channel equalization method of equalizing a signal received over a transmission channel, the method including filtering the received signal using a feedforward filter, filtering a signal that is previously filtered using a feedback filter, subtracting a first filter signal filtered by the feedback filter from a second filter signal filtered by the feedforward filter to determine a difference signal, determining a first level value among a plurality of predetermined amplitude levels based on an amplitude of the difference signal, calculating a first error value based on the amplitude of the difference signal and the first level value, and updating respective tap coefficients of the feedforward filter and the feedback filter using the first error value.

The method may further include outputting a decision value to decide the difference signal as the previously equalized signal.

The plurality of predetermined amplitude levels may be set based on an amplitude of constellations of the signal received over the transmission channel.

The determining of the first level value may include comparing the amplitude of the difference signal with the plurality of predetermined amplitude levels to determine a most approximate level value as the first level value.

The determining of the first level value may include determining the first level value using a threshold defined by the MAP (Maximum a posteriori) rule.

The threshold may be determined according to a signal-to-noise (SNR) ratio.

The method may further include calculating a second error value by applying the CMA algorithm to the amplitude of the difference signal, wherein the updating of the respective tap coefficients may include updating the respective tap coefficients based on the first error value and the second error value.

The updating of the respective tap coefficients may include updating the respective tap coefficients using the first error value if a sign of the first error value and a sign of the second error value are the same.

The updating of the respective tap coefficients may include not updating the respective tap coefficients if a sign of the first error value and a sign of the second error value are not the same.

The updating of the respective tap coefficients may include updating the respective tap coefficients using a weighted sum of the first error value and the second error value.

The first error value may be obtained by the following equation:
e^{LDD}(n)=sgn(z(n))(|z(n)(|z(n)|−_{\hat{α}}(n)²)
where z(n) is an output signal from the equalizer, and \hat{α}(n) is the first level value.

Preferably, the first error value is obtained by the equation as follows:
e^{LDD}(n)=z(n)(|z(n)|²−_{\hat{α}}(n)²)
wherein, z(n) is an output signal from the equalizer, and _{\hat{α}}(n) is the first level value.

### BRIEF DESCRIPTION OF THE DRAWINGS

These and/or other aspects of the present general inventive concept will become apparent and more readily appreciated from the following description of the embodiments, taken in conjunction with the accompanying drawings of which:

FIG. 1 is a functional block diagram illustrating a conventional decision feedback equalizer (DFE), which updates a tap coefficient using a Stop-and-Go (SAG) algorithm;

FIGS. 2A and 2B are diagrams illustrating the SAG algorithm;

FIG. 3 is a functional block diagram illustrating a DFE according to an embodiment of the present general inventive concept;

FIGS. 4A and 4B are diagrams illustrating an error signal calculation method according to an embodiment of the present general inventive concept; and

FIG. 5 is a flow chart illustrating a channel equalization method according to an embodiment of the present general inventive concept.

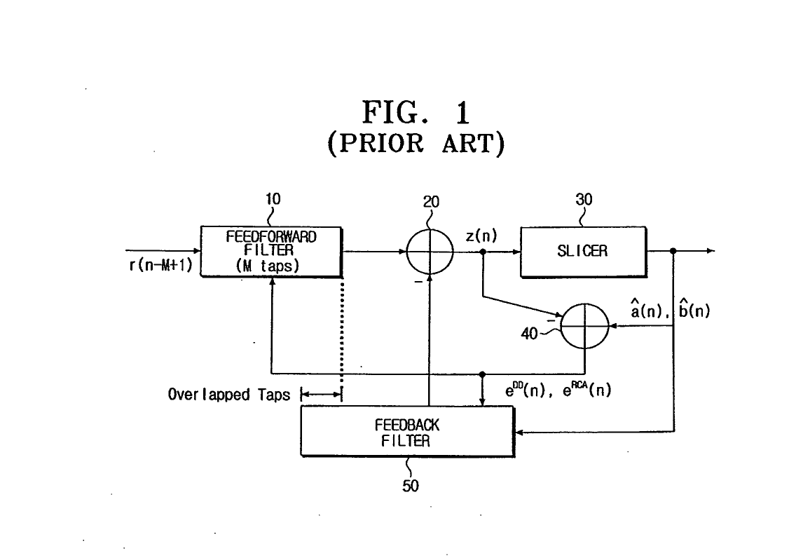

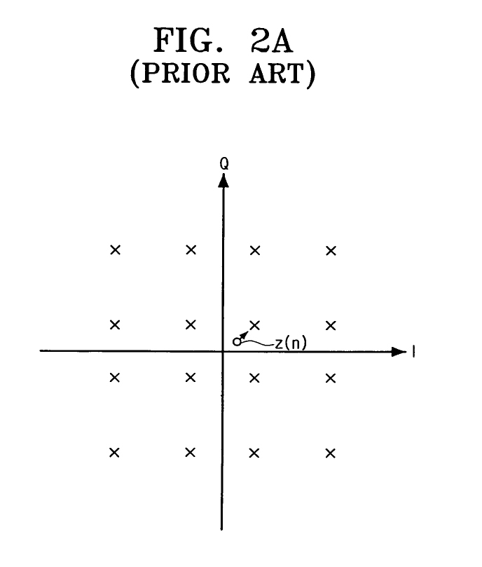

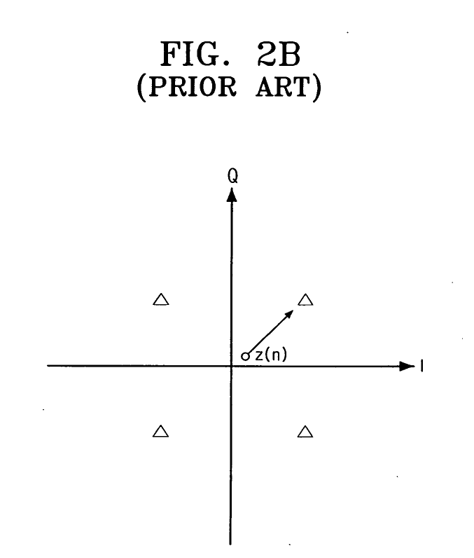

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

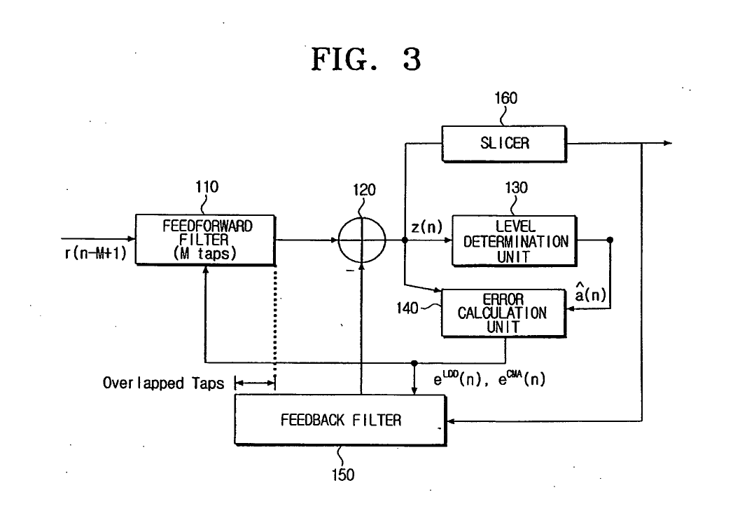

FIG. 3 is a functional block diagram illustrating a decision feedback equalizer (DFE) according to an embodiment of the present general inventive concept. The equalizer includes a feedforward filter 110, a subtracter 120, a level determination unit 130, an error calculation unit 140, a feedback filter 150, and/or a slicer 160.

The feedforward filter 110 filters a signal transmitted and received over a transmission channel. The filtering performed by the feedforward filter 110 cancels a pre-ghost.

The feedback filter 150 filters a signal which has been previously equalized by the channel equalizer (i.e., the DFE). This signal may be an output signal z(n) from the first subtracter 120, or a slicer output signal (if the slicer 160 is included in the DFE). The output of the slicer 160 has undergone a decision-directed operation. The feedback filter 150 may remove a post-ghost from the signal.

The subtracter 120 subtracts a first signal, which has been filtered by the feedback filter 150, from a second signal, which has been filtered by the feedforward filter 110, and outputs the resulting signal z(n). This output signal z(n) corresponds to a signal from a receiver, from which the pre-ghost and the post-ghost components are removed. The slicer 160 computes a decision based on the output signal z(n) from the subtracter 120 and outputs a decision value.

The level determination unit 130 determines a first level value \hat{α}(n) from among a plurality of amplitude levels based on an amplitude of the output signal z(n) of the subtracter 120. The plurality of amplitude levels may be predetermined.

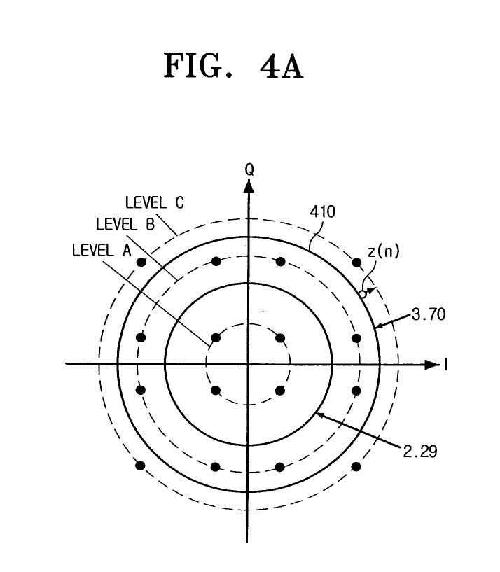

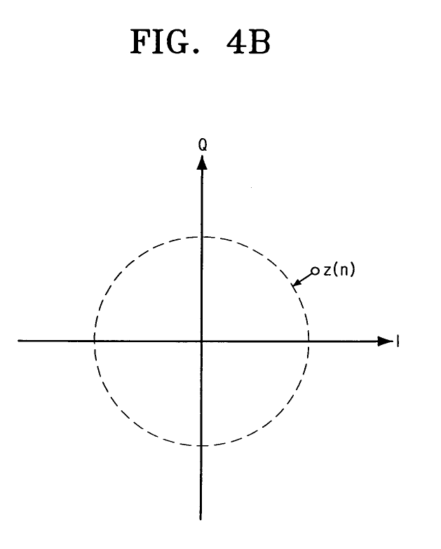

The plurality of amplitude levels are set based on a constellation amplitude and an amplitude of the signal transmitted over the transmission channel. That is, the amplitude level defines the constellation amplitude of the signal transmitted over the transmission channel. For instance, FIG. 4A illustrates respective constellation points having {±1, ±3} levels in a 16-QAM mode. As can be seen in FIG. 4, there are 3 amplitude levels in the 16-QAM mode. The constellation points are represented in FIG. 4A as black dots. Here, level “A” is

\sqrt{2}(=\sqrt{1²+1²}), level “B” is \sqrt{10}(=\sqrt{1²+3²}), and level “C” is \sqrt{18}(=\sqrt{3²+3²}).

A method of determining the first level value from among the plurality of amplitude levels being set will now be described. For convenience, it is assumed that the output signal z(n) from the subtracter 120 is positioned between the level “B” and the level “C”.

Among the level “B” and the level “C”, a threshold 410 to determine the first level value can be obtained by the maximum a posterior (MAP) rule. Since the number of constellation points existing at the level “B” is greater than the number of constellations existing at the level “C”, there is a very high possibility that the signal z(n) should be placed at the level “B”, not the level “C”. Therefore, it is probable that the threshold 410 will have a larger value than the median between the level “B” and the level “C”. If an amplitude |z(n)| of the output signal of the subtractor 120 (i.e., the filtered signal) is larger than the threshold 410, the level “C” is determined as the first level value, whereas if the amplitude |z(n)| of the filtered signal is smaller than the threshold 410, the level “B” is determined as the first level value.

Here, the threshold 410 may be determined according to a signal to noise ratio (SNR). Since accuracy of the signal transmitted to a receiving end gets relatively high if the SNR is high, the threshold 410 can be set to a value close to the median between levels. For instance, FIG. 4A illustrates thresholds having {±1, ±3} levels in the 16-QAM mode, when the SNR is high.

The level determination unit 130 compares the amplitude |z(n)| of the output signal z(n) of the subtracter 120 (i.e., the filtered signal) with a predetermined amplitude level, and determines the more approximate one as a first level value \hat{α}(n). The threshold 410 at this time is a median between levels.

The error calculation unit 140 calculates a first error value based on the amplitude |z(n)| of the output signal z(n) from the subtractor 120 and the first level value \hat{α}(n), and outputs the first error value to the feedforward filter 110 and the feedback filter 150, respectively, so that the feedforward and feedback filters 110 and 150 may update their respective tap coefficients using the first error value.

The first error value can be obtained using the level decision-directed (DD) algorithm. In the present embodiment, the following equations may be used to calculate the first error value.
e^{LDD}(n)=sgn(z(n))(|z(n)|−_{\hat{α}}(n)) [Equation 4]
e^{LDD}(n)=z(n)(|z(n)|²−_{\hat{α}}(n)²) [Equation 5]

Besides the above equations, the first error value can be obtained by a variety of methods (e.g., an error performance curve has a global minimum in its concave shape).

Unlike the conventional methods, the channel equalizer (i.e., the DFE) of the embodiments of present general inventive concept uses the amplitude of the filtered signal, |z(n)|, not the output signal z(n) (i.e., the actual filtered signal), from the channel equalizer. Thus, the channel equalizer may be operated independent of phase error. This feature also allows a variety of designs for the channel equalizer according to various embodiments of the present general inventive concept regardless of a sequence of a carrier recovery operation and a channel equalization operation with respect to one another.

The error calculation unit 140 also calculates a second error value by applying a constant modulus algorithm (CMA) to the amplitude |z(n)| of the filtered signal z(n) from the subtracter 120, and outputs the second error value to the feedforward filter 110 and the feedback filter 150, respectively, so that the feedforward and feedback filters 110 and 150 may update their respective tap coefficients based on the first and second error values.

The second error value can be obtained using the CMA as follows:
e^{CMA}(n)=z(n)|z(n)|^{P-2}(|z(n)|^{P}−Rₚ)
where P is a positive integer, and R_{P} is a level value of the CMA determined as follows:
R_{P}=E{|α(n)|^{2P}}/E{|α(n)|^{P}}
where a(n) represents a constellation of the signal transmitted over the transmission channel, and P is usually 2. As can be seen in FIG. 4B, the CMA has one level value R_{P}.

A method of updating a tap coefficient of the feedforward filter 110 and of the feedback filter 150 based on the first error value and the second error value will now be described.

As mentioned above, the least mean square (LMS) algorithm is typically used to update a tap coefficient of a filter. The filter coefficient updating equation based on the LMS algorithm is provided above in Equation 1.

In the present embodiment, an error signal e^{LDD} derived using the level DD algorithm is used as an error signal e(n). The SAG algorithm adopted by the present embodiment for a tap coefficient updating operation can be expressed as follows:
W_{R}(n+1)=W_{R}(n)−μ(f_{n,R}e_{R}^{LDD}(n)r_{R}(n)+f_{n,I}eₗ^{LDD}(n)r(n))
W_{I}(n+1)=W(n)+μ(f_{n,R}e_{R}^{LDD}(n)r_{I}(n)−η_{n,I}e_{I}^{LDD}(n)r_{R}(n))
where W_{R}(n) represents a real number part of a tap coefficient vector w(n), and wₗ(n) represents an imaginary number part of the tap coefficient vector w(n). Also, e_{R}_{LDD} and eₗ^{LDD} represent a real number part and an imaginary number part of the error signal derived using the level DD algorithm e^{LDD}, and f_{n,R} and f_{n,l} have values as follows:
f_{n,R}=1, if sgn(e_{R}^{LDD}(n))=sgn(e_{R}^{CMA}(n)) AND f_{r,R}=0, otherwise
f_{n,I}=1, if sgn(e_{I}^{LDD}(n))=sgn(e_{I}^{CMA}(n)) AND f_{n,I}=0, otherwise

The tap coefficient(s) of the filter(s) (e.g., the feedforward and feedback filters 110 and 150) is updated when the sign of the e^{LDD} derived using the level DD algorithm and the sign of the error signal e^{CMA} derived using the CMA are the same. In other words, the real number part of the e^{LDD} can be reflected in the tap coefficient updating process if the sign of the real number part of the e^{LDD} and the sign of the real number part of the error signal e^{CMA} are the same. Similarly, the imaginary number part of the e^{LDD} can be reflected in the tap coefficient updating process if the sign of the imaginary number part of the e^{LDD} and the sign of the imaginary number part of the error signal e^{CMA} are the same. Because the two algorithms including the level DD algorithm and the CMA are used to decide whether the error signal e(n) obtained by the error calculation unit 140 should be reflected in tap coefficient updating, an accuracy of the tap coefficient updating operation can be improved.

The tap coefficient(s) of the filter(s) (e.g., the feedforward and feedback filters 110 and 150) is not updated if the sign of the e^{LDD} and the sign of the error signal e^{CMA} are different.

According to another embodiment of the present general inventive concept, a weighted sum e^{T}(n) of the error signal e^{LDD} derived using the level DD algorithm and the error signal e^{CMA} derived using the CMA may be used as the error signal e(n). The weighted sum e^{T}(n) can be expressed as follows:
e^{T}(n)=α·e^{LDD}(n)+β·e^{CMA}(n)
where α and β are weights, and α+β=1. As such, the accuracy of the tap coefficient updating process can be improved even more by using not only the error signal e(n) derived from one algorithm (i.e., e^{LDD} derived from the level decision directed (LDD) algorithm), but the weighted sum e^{T}(n) of error signals derived using two algorithms (i.e., both LDD and the CMA). Thus, the tap coefficient updating equation of Equation 1 can be rewritten by substituting the error signal e^{T}.
w(n+1)=w(n)−μr(n)e^{T}(n)

The above-described operations and methods can be implemented by a channel equalizer without the feedback filter 150. In this case, the channel equalizer includes a feedforward filter 110, a level determination unit 130, an error calculating unit 140, and/or a slicer 160. Thus, an output signal from the feedforward filter 110 is inputted to the level determination unit 130, the error calculation unit 140 and the slicer 160 (if the slicer 160 is included in the channel equalizer), respectively. In this case, the subtractor 120 would not be used. The slicer 160 need not be included in the channel equalizer.

The level determination unit 130 determines a first level value α(n) among a plurality of predetermined amplitude levels, based on an amplitude |z(n)| of an output signal z(n) of the feedforward filter 110.

The error calculation unit 140 calculates a first error value based on the amplitude |z(n| of the output signal z(n) of the feedforward filter 110 and the first level value \hat{α}(n), and outputs the first error value to the feedforward filter 110 so that the feedforward filter 110 may update the tap coefficients using the first error value.

The error calculation unit 140 also calculates a second error value by applying the CMA to the amplitude |z(n)| of the output signal z(n) from the feedforward filter 110, and outputs the second error value to the feedforward filter 110 so that the feedforward filter 110 may update the tap coefficients based on the first and second error values.

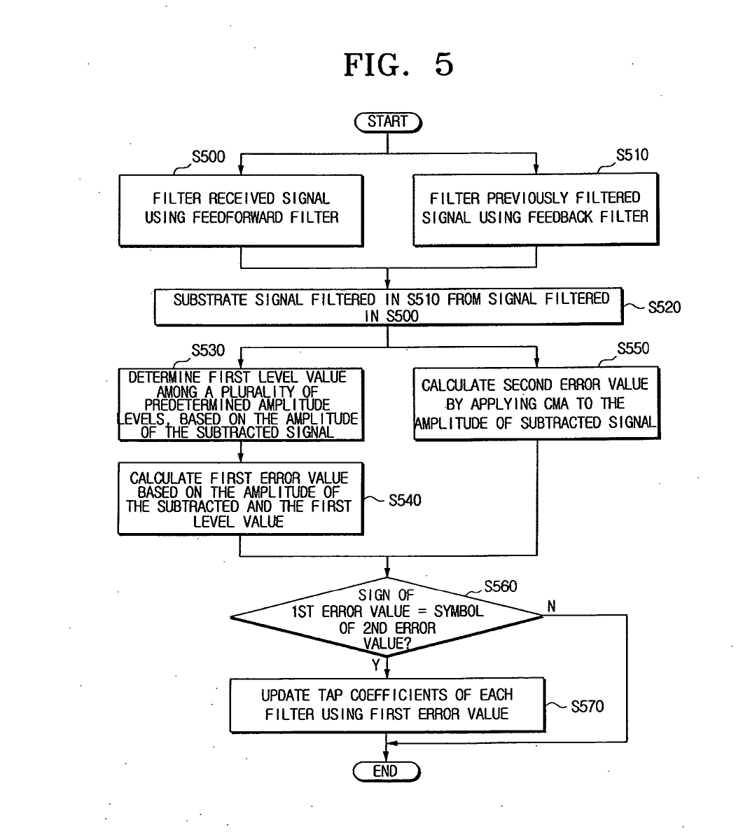

FIG. 5 is a flow chart illustrating a channel equalization method according to an embodiment of the present general inventive concept. The method of FIG. 5 may be performed by the DFE (i.e., the channel equalizer) of FIG. 3. Accordingly, for illustration purposes, the method of FIG. 5 is described below with reference to FIGS. 3 to 5.

In operation S500, the feedforward filter 110 performs filtering on the signal transmitted and received over the transmission channel.

In operation S510, the feedback filter 150 performs filtering on the previously equalized signals.

In operation S520, the filtered signal that is filtered in the operation S510 is subtracted from the filtered signal that is filtered in the operation S500. The resulting signal z(n) corresponds to a signal from a receiver, from which the pre-ghost and the post-ghost components are removed.

In operation 530, a first level value among the plurality of amplitude levels is determined based on the amplitude |z(n)| of the signal z(n) obtained in the operation S520. The methods of setting amplitude levels and determining the first level value are explained above.

In operation S540, a first error value (e^{LDD}) is calculated based on the amplitude |z(n)| of the signal z(n) obtained in the operation S520 and the first level value using the level decision-directed algorithm (DD).

In operation S550, a second error value (e^{CMA}) is calculated by applying the CMA to the amplitude |z(n)| of the signal z(n) obtained in the operation S520.

The methods of calculating the first and second error values are explained above.

In operation S560, it is determined whether the sign of the first error value e^{LDD} and the sign of the second error value e^{CMA} are the same. If the signs are the same (the operation S560:Y), in operation S570, the tap coefficients of the feedforward filter 110 and the feedback filter 150 are updated using the first error value (e^{LDD}). Otherwise (the operation S560:N), the tap coefficients of the filters are not updated.

In more detail, if the real number part of the first error value e^{LDD} and the real number part of the second error valve e^{CMA} have the same sign (the operation S560:Y), the real number part of the e^{LDD} may be reflected in the tap coefficient updating process (the operation S570). Likewise, if the imaginary number part of the first error valve e^{LDD} and the imaginary number part of the second error valve e^{CMA} have the same sign (the operation S560:Y), the imaginary number part of the e^{LDD} may be reflected in the tap coefficient updating process (the operation S570).

Alternatively, the weighted sum e^{T}(n) of the error signal e^{LDD} derived using the Level DD algorithm and the error signal e^{CMA} derived using the CMA may also be used as the error signal e(n) instead of the operations S560 and S570.

The channel equalization method of the embodiments of the present general inventive concept can be implemented in a channel equalizer with or without the feedback filter 150.

A channel equalizer of the various embodiments of the present general inventive concept operates independently of phase error by using an amplitude of a received signal in channel equalization, whereby a variety of designs can be available for the channel equalizer regardless of a sequence of a carrier recovery operation and a channel equalization operation.

Moreover, since a channel equalization method of the various embodiments of the present general inventive concept does not require a training sequence, but instead uses an error signal derived using the Level DD algorithm for a tap coefficient updating process, a corresponding steady-state mean square error (MSE) is relatively smaller than an MSE of the CMA algorithm.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A channel equalizer to equalize a signal received over a transmission channel, comprising:
a feedforward filter to filter the received signal;
a level determination unit to determine a first level value among a plurality of predetermined amplitude levels based on an amplitude of an output signal of the feedforward filter; and
an error calculation unit to calculate a first error value based on the amplitude of the output signal of the feedforward filter and the first level value and to output the first error value to the feedforward filter so that the feedforward filter updates a tap coefficient thereof using the first error value.

2. The channel equalizer of claim 1, wherein the plurality of predetermined amplitude levels are set based on amplitude(s) of constellations of the signal received over the transmission channel.

3. The channel equalizer of claim 1, wherein the level determination unit determines the first level value using a threshold defined by the maximum a posteriori (MAP) rule.

4. The channel equalizer of claim 1, wherein the first error value is obtained by the following equation:
e^{LDD}(n)=sgn(z(n))(|z(n)|−_{\hat{α}}(n))
where z(n) is an output signal of the equalizer, and \hat{α}(n) is the first level value.

5. The channel equalizer according to claim 1, wherein the first error value is obtained by the following equation:
e^{LDD}(n)=z(n)(|z(n)|²−_{\hat{α}}(n)²)
where z(n) is an output signal of the equalizer, and \hat{α}(n) is the first level value.

6. The channel equalizer of claim 1, wherein the error calculation unit calculates a second error value by applying the CMA algorithm to the amplitude of the output signal of the feedforward filter and outputs the second error value to the feedforward filter such that the feedforward filter updates the tap coefficient thereof based on the first error value and the second error value.

7. The channel equalizer of claim 6, wherein, if a sign of the first error value and a sign of the second error value are the same, the feedforward filter updates the tap coefficient thereof using the first error value.

8. The channel equalizer of claim 6, wherein, if a sign of the first error value and a sign of the second error value are not the same, the feedforward filter does not update the tap coefficient thereof.

9. The channel equalizer of claim 6, wherein the feedforward filter updates the tap coefficient thereof using a weighted sum of the first error value and the second error value.

10. A channel equalizer to equalize a signal received over a transmission channel, comprising:
a feedforward filter to filter the received signal;
a feedback filter to filter a signal previously filtered by the channel equalizer;
a subtracter to subtract a first filter signal filtered by the feedback filter from a second filter signal filtered by the feedforward filter and to output a resulting signal;
a level determination unit to determine a first level value among a plurality of predetermined amplitude levels based on an amplitude of the output signal of the subtracter; and
an error calculation unit calculate a first error value based on the amplitude of the output signal of the subtracter and the first level value and to output the first error value to the feedforward filter and the feedback filter so that the feedforward filter and the feedback filter update respective tap coefficients thereof using the first error value.

11. The channel equalizer of claim 10, further comprising:
a slicer to output a decision value deciding the output signal from the subtracter as the previously filtered signal.

12. The channel equalizer of claim 10, wherein the plurality of predetermined amplitude levels are set based on an amplitude of constellations of the signal received over the transmission channel.

13. The channel equalizer of claim 10, wherein the level determination unit compares the amplitude of the output signal of the subtracter with the plurality of predetermined amplitude levels to determine a most approximate level value as the first level value.

14. The channel equalizer of claim 10, wherein the level determination unit determines the first level value using a threshold defined by the MAP (maximum a posteriori) rule.

15. The channel equalizer of claim 14, wherein the threshold is determined according to a signal-to-noise (SNR) ratio.

16. The channel equalizer of claim 10, wherein the first error value is obtained by the following equation:
e^{LDD}(n)=sgn(z(n))(|z(n)|−_{\hat{α}}(n))
where z(n) is an output signal of the equalizer and \hat{α}(n) is the first level value.

17. The channel equalizer of claim 10, wherein the first error value is obtained by the following equation:
e^{LDD}(n)=z(n))(|z(n)|²−_{\hat{α}}(n)²)
where z(n) is an output signal of the equalizer, and \hat{α}(n) is the first level value.

18. The channel equalizer of claim 1, wherein the error calculation unit further calculates a second error value by applying a constant modulus algorithm (CMA) to the amplitude of the output signal of the subtractor and outputs the second error value to the feedforward filter and the feedback filter such that the feedforward filter and the feedback filter update the respective tap coefficients thereof based on the first error value and the second error value.

19. The channel equalizer of claim 18, wherein, if a sign of the first error value and a sign of the second error value are the same, the feedforward filter and the feedback filter update the respective tap coefficients thereof using the first error value.

20. The channel equalizer of claim 18, wherein, if a sign of the first error value and a sign of the second error value are not the same, the feedforward filter and the feedback filter do not update the respective tap coefficients thereof.

21. The channel equalizer of claim 18, wherein the feedforward filter and the feedback filter update the respective tap coefficients thereof using a weighted sum of the first error value and the second error value.

22. A channel equalizer, comprising:
at least one filter having a plurality of taps and corresponding tap coefficients; and
an error unit to determine an error based on amplitude information of an output of the at least one filter and to feedback the error to the at least one filter such that the at least one filter controls the tap coefficients accordingly.

23. The channel equalizer of claim 22, wherein the at least one filter updates the tap coefficients using a least mean squares algorithm based on the feedback error.

24. The channel equalizer of claim 22, wherein the error comprises a level decision-directed error signal.

25. The channel equalizer of claim 22, wherein the error comprises a first error as a level decision directed (LDD) error signal and a second error as a constant modulus algorithm (CMA) error signal.

26. The channel equalizer of claim 25, wherein if a sign of the first error is the same as a sign of the second error, the tap coefficients are updated using a least mean squares algorithm based on the first error.

27. The channel equalizer of claim 25, wherein if a sign of the first error is the same as a sign of the second error, the tap coefficients are updated using a least mean squares algorithm based on a weighted sum of the first error and the second error.

28. A receiver, comprising:
a channel equalizer, including
at least one filter having a plurality of taps and corresponding tap coefficients, and
an error unit to determine an error based on amplitude information of an output of the at least one filter and to feedback the error to the at least one filter such that the at least one filter controls the tap coefficients accordingly.

29. The receiver of claim 28, wherein the channel equalizer performs channel equalization before a carrier recovery operation is performed.

30. The receiver of claim 28, wherein the channel equalizer performs channel equalization at the same time or after a carrier recovery operation is performed.

31. A method of updating a tap coefficient of a filter in a channel equalizer which equalizes a signal received over a transmission channel, the method comprising:
determining a first level value among a plurality of predetermined amplitude levels based on an amplitude of an output signal of the filter;
calculating a first error value based on the amplitude of the output signal of the filter and the first level value; and
updating the tap coefficient using the first error value.

32. The method of claim 31, wherein the plurality of predetermined amplitude levels are set based on an amplitude of constellations of the signal received over the transmission channel.

33. The method of claim 31, wherein the determining of the first level value comprises determining the first level value using a threshold defined by the maximum a posteriori (MAP) rule.

34. The method of claim 31, further comprising:
generating a second error value by applying a constant modulus algorithm (CMA) to the amplitude of the output signal of the filter,
wherein the updating of the tap coefficient comprises updating the tap coefficient based on the first error value and the second error value.

35. The method of claim 34, wherein the updating of the tap coefficient comprises updating the tap coefficient using the first error value if a sign of the first error value and a sign of the second error value are the same.

36. The method of claim 34, wherein the updating of the tap coefficient comprises not updating the tap coefficient if a sign of the first error value and a sign of the second error value are not the same.

37. The method of claim 34, wherein the updating of the tap coefficient comprises updating the tap coefficient using a weighted sum of the first error value and the second error value.

38. A channel equalization method of equalizing a signal received over a transmission channel, the method comprising:
filtering the received signal using a feedforward filter;
filtering a signal that is previously filtered using a feedback filter;
subtracting a first filter signal filtered by the feedback filter from a second filter signal filtered by the feedforward filter to determine a difference signal;
determining a first level value among a plurality of predetermined amplitude levels based on an amplitude of the difference signal;
calculating a first error value based on the amplitude of the difference signal and the first level value; and
updating respective tap coefficients of the feedforward filter and the feedback filter using the first error value.

39. The method of claim 38, further comprising:
outputting a decision value to decide the difference signal as the previously filtered signal.

40. The method of claim 38, wherein the plurality of predetermined amplitude levels are set based on an amplitude of constellations of the signal received over the transmission channel.

41. The method of claim 38, wherein the determining of the first level value comprises comparing the amplitude of the difference signal with the plurality of predetermined amplitude levels to determine a most approximate level value as the first level value.

42. The method of claim 38, wherein the determining of the first level value comprises determining the first level value using a threshold defined by the MAP (maximum a posteriori) rule.

43. The method of claim 42, wherein the threshold is determined according to a signal-to-noise (SNR) ratio.

44. The method of claim 38, wherein the first error value is obtained by the following equation:
e^{LDD}(n)=sgn(z(n))(|z(n)|−_{\hat{α}}(n))
where z(n) is an output signal of the equalizer and \hat{α}(n) is the first level value.

45. The method of claim 38, wherein the first error value is obtained by the following equation:
e^{LDD}(n)=z(n)(|z(n)|²−_{\hat{α}}(n)²)
where z(n) is an output signal of the equalizer, and \hat{α}(n) is the first level value.

46. The method of claim 38, further comprising:
calculating a second error value by applying a constant modulus algorithm (CMA) to the amplitude of the difference signal,
wherein the updating of the respective tap coefficients comprises updating the respective tap coefficients based on the first error value and the second error value.

47. The method of claim 46, wherein the updating of the respective tap coefficients comprises updating the respective tap coefficients using the first error value if a sign of the first error value and a sign of the second error value are the same.

48. The method of claim 46, wherein the updating of the respective tap coefficients comprises not updating the respective tap coefficients if a sign of the first error value and a sign of the second error value are not the same.

49. The method of claim 46, wherein the updating of the respective tap coefficients comprises updating the tap coefficients using a weighted sum of the first error value and the second error value.

50. An equalization method, the method comprising:
determining an error based on amplitude information of an output of at least one filter; and
feeding the determined error back to the at least one filter such that the at least one filter controls tap coefficients thereof accordingly.
